(19) United States
(12) Patent Application Publication
(10) Pub. No.: US 2004/0065957 A1
(43) Pub. Date: Apr. 8, 2004

(54) Semiconductor device having a low dielectric film and fabrication process thereof

(76) Inventors: Kaoru Maekawa, Yamanashi (JP); Masahito Sugiura, Yamanashi (JP)

Correspondence Address: Finnegan Henderson Farabow, Garrett & Dunner, 1300 I Street NW, Washington, DC, 20005-3315, US

(21) Appl. No.: 10/258,475

(22) PCT Filed: Apr. 26, 2001
(86) PCT No.: PCT/JP01/03618

(30) Foreign Application Priority Data
Apr. 28, 2000 (JP) 2000-131378

(51) Int. Cl. H01L 21/4763; H01L 23/48; H01L 29/40

(52) U.S. Cl. 257/758; 438/638; 438/723; 438/738; 438/743

(57) ABSTRACT

A method of fabricating a semiconductor device includes the step of depositing a second insulating film on a first insulating film, patterning the second insulating film to form an opening therein, and etching the first insulating film while using the second insulating film as an etching mask, wherein a low-dielectric film is used for the second insulating film.

### TECHNICAL FIELD

The present invention generally relates to semiconductor devices and more specifically to a semiconductor device having a low-dielectric film and a fabrication process thereof.

### BACKGROUND ART

With the progress in the art of high-resolution lithography, leading-edge semiconductor integrated circuit devices of these days include enormous number of semiconductor devices on a substrate. In such advanced semiconductor integrated circuit devices, the use:of a single interconnection layer is not sufficient for interconnecting the semiconductor devices on the substrate, and it is practiced to provide a multilayer interconnection structure on the substrate, wherein a multilayer interconnection structure includes a plurality of interconnection layers stacked with each other with intervening interlayer insulating films.

Particularly, there is an intensive effort made with regard to the so-called dual-damascene process in the art of multilayer interconnection structure in which a typical dual-damascene process includes the steps of forming grooves and contact holes in an interlayer insulating film in correspondence to the interconnection patterns to be formed, and filling the grooves and the contact holes by a conducting material to form the desired interconnection pattern.

When conducting such a dual-damascene process, the grooves and contact holes are formed while using an etching stopper film, and thus the role of the etching stopper film is very important in the art of dual-damascene processes. Further, etching stopper films play an important role also in the art of SAC (self-aligned contact), in which-extremely minute contact holes, exceeding the resolution limit of lithography, are formed in an insulating film of a semiconductor device.

While there exist various modifications in the dual-damascene process, the processes in FIGS. 1A-1F represent a typical conventional dual-damascene process used for forming a multilayer interconnection structure.

Referring to FIG. 1A, a Si substrate 10, carrying thereon various semiconductor device elements such as MOS (Metal-Oxide-Silicon) transistors not illustrated, is covered by an interlayer insulating film 11 such as a CVD (Chemical Vapor Deposition)-SiO₂ film, and the interlayer insulating film 11 carries thereon an interconnection pattern 12A. It should be noted that the interconnection pattern 12A is embedded in a next interlayer insulating film 12B formed on the interlayer insulating film 11, and an etching stopper film 13 of SiN, and the like, is provided so as to cover the interconnection pattern 12A and the interlayer insulating film 12B.

The etching stopper film 13, in turn, is covered by another interlayer insulating film 14, and the interlayer insulating film 14 is covered by another etching stopper film 15.

In the illustrated example, there is a further interlayer insulating film 16 formed on the etching stopper film 15, and the interlayer insulating film 16 is covered by a next etching stopper film 17. The etching stopper films 15 and 17 are also called as “hard mask.”

In the step of FIG. 1A, a resist pattern 18 is formed on the etching stopper film 17 with a resist opening 18A formed in correspondence to a desired contact hole by a photolithographic patterning process, and the etching stopper film 17 is removed by a dry etching process while using the resist pattern 18 as a mask. As a result, there is formed an opening corresponding to the desired contact hole in the etching stopper film 17.

Next, in the step of FIG. 1B, the resist pattern 18 is removed and the interlayer insulating film 16 underlying the etching stopper film 17 is subjected to an RIE (Reactive Ion Etching) process while using the etching stopper film 17 as a hard mask. As a result, an opening 16A is formed in the interlayer insulating film 16 in correspondence to the desired contact hole.

Next, in the step of FIG. 1C, a resist film 19 is formed on the structure of FIG. 1B so as to fill the opening 16A, and the resist film 19 is patterned subsequently in the step of FIG. 1D by a photolithographic patterning process so as to form a resist opening 19A corresponding to a desired interconnection pattern. As a result of formation of the resist opening 19A, the opening 16A in the interlayer insulating film 16 is exposed.

In the step of FIG. 1D, the etchings stopper film 17 exposed by the resist opening 19A and the etching stopper film 15 exposed at the bottom of the opening 16A are removed by a dry etching process, and the resist pattern 19 is removed in the step of FIG. 1E. Further, the interlayer insulating film 16 and the interlayer insulating film 14 are patterned simultaneously while using the etching stopper films 17 and 15 as a hard mask.

As a result of the patterning, there is formed a groove 16B corresponding to the desired interconnection pattern in the interlayer insulating film 16 and a hole 14A is formed in the interlayer insulating film 14 in correspondence to the desired contact hole. It should be noted that the interconnection groove 16B is formed so as to include the contact hole 16A.

Next, in the step of FIG. 1F, the etching stopper film 13 exposed at the bottom of the contact hole 14A is removed by an RIE process, causing exposure of the interconnection pattern 12A at the bottom of the contact hole 14A.

After the foregoing step of removing the etching stopper film 13, a conductor layer such as an Al layer or a Cu layer is formed on the interlayer insulating film 16 so as to fill the interconnection groove 16B and the contact hole 14A, wherein the conductor layer thus deposited is subsequently subjected to a chemical mechanical polishing (CMP) process and the part of the conductor layer locating above the top surface of the interlayer insulating film 16 is removed. As a result, an interconnection pattern 20 is obtained in the interconnection groove 16B in electrical contact with the underlying interconnection pattern 12A via the contact hole 14A. Interconnection patterns of third and fourth layers can be formed similarly by repeating the foregoing process steps.

In such a dual damascene process for forming a multilayer interconnection structure, the role of the etching stopper films 13, 15 and 17 is important as noted previously. Conventionally, it has been practiced to use SiN for the material of the etching stopper films 13, 15 and 17 in view of the large difference of etching rate with respect to the materials used for the interlayer insulating films 14, 16 and 18.

Meanwhile, recent advanced semiconductor integrated circuits tend to use Cu having a characteristically low resistance as the material of the interconnection pattern in place of conventionally used Al, for minimizing signal delay caused in the interconnection patterns. In such advanced semiconductor integrated circuits, the problem of signal delay in the interconnection patterns is becoming a serious problem in view of the enormous number of the semiconductor device elements formed on a common substrate and in view of increased complexity, and hence increased total length, of the interconnection patterns formed in the multilayer. interconnection structure.

In order to reduce the signal delay as much as possible, intensive efforts are being made, in addition to the use of Cu interconnection patterns, so as to reduce the dielectric constant of the interlayer insulating film constituting the multilayer interconnection structure. In the event SiO₂ or BPSG is used for an interlayer insulating film as in the case of conventional multilayer interconnection structures, it should be noted that the specific dielectric constant of the interlayer insulating film generally takes a value of 4-5. This value of the specific dielectric constant can be reduced to 3.3-3.6 by using a F (fluorine)-doped SiO₂ film called FSG. Further, the value-of the specific dielectric constant can be reduced 2.9-3.1 by using an SiO₂ film having a Si—H group in the structure thereof such as an HSQ (hydrogen silsesquioxane) film. Further, the use of an organic SOG or organic insulating film is proposed. In the case an organic SOG is used, it becomes possible to reduce the specific dielectric constant to below 3.0. Further, the use of an organic insulating film can realize a still lower specific dielectric constant of about 2.7.

In a multilayer interconnection structure formed by a dual damascene process explained with reference to FIGS. 1A-1F, it is essential to interpose an etching stopper film between one interlayer insulating film and a next interlayer insulating film. When SiN is used for such an etching stopper as in the conventional multilayer interconnection structure, on the other hand, the large specific dielectric constant of SiN, which takes a value of about 8, cancels out the advantageous effect of using the low-dielectric interlayer insulating film substantially. Thus, the effort to reduce the resistance of the interconnection pattern by using Cu in combination with the use of a low-dielectric interlayer insulating film is substantially undermined by the high specific dielectric constant of SiN. As can be seen, the etching stopper film remains in the multilayer interconnection structure after the dual damascene process is completed.

In the case an organic insulating film is used for the interlayer insulating film, it is possible to use SiO₂ for the etching stopper layer. In this case, too, the existence of the SiO₂ etching stopper film cancels out the desired low dielectric constant of the interlayer insulating film to substantial extent.

It should be noted that the etching stopper film remains in the final device structure also in the case of semiconductor devices having a SAC (self-aligned contact) structure. In a SAC structure, an etching stopper film is used as a self-aligned mask during the process of forming a contact hole. For example, such a self-aligned mask is provided in the form of a sidewall insulating film of a gate electrode. Thus, the use of a low-dielectric material for the self-aligned mask in a SAC structure is an important point for improving the operational speed of a semiconductor device. Conventionally, SiN or SiON has been used for this purpose, while these materials have a specific dielectric constant of larger than 4.0 and the desired improvement of operational speed of the semiconductor device has been not achieved.

### DISCLOSURE OF THE INVENTION

Accordingly, it is a general object of the present invention to provide a novel and useful semiconductor device and fabrication process thereof wherein the foregoing problems are eliminated.

Another and more specific object of the present invention is to reduce the dielectric constant of an etching stopper film used in a semiconductor device having a multilayer interconnection structure as a hard mask.

Another object of the present invention is to reduce the dielectric constant of an etching stopper film used in a semiconductor device having a self-aligned contact hole as a self-aligned mask.

Another object of the present invention is to provide a fabrication process of a semiconductor device, comprising the steps of:

depositing a second insulating film on a first insulating film;

patterning said second insulating film to form an opening therein; and

etching said first insulating film while using said second insulating film as a mask,

wherein a low-dielectric film is used for said second insulating film.

Another object of the present invention is to provide a semiconductor device, comprising:

a substrate; and

a multilayer interconnection structure provided on said substrate,

said multilayer interconnection structure comprising:

an interlayer insulating film having a first opening;

an etching stopper film provided on said interlayer insulating film with a second opening aligned with said first opening; and

a conductor pattern filling said first and second openings,

wherein said etching stopper film is formed of a low-dielectric film.

Another object of the present invention is to provide a semiconductor device, comprising:

a substrate;

a pair of patterns formed on said substrate; and

a contact hole formed between said pair of patterns,

each of said patterns having a sidewall insulating films thereon, and

wherein said contact hole is defined by said side wall insulating films of said patterns,

said sidewall insulating films comprising a material having a low-dielectric constant.

According to the present invention, it is possible to minimize the signal delay caused in the multilayer interconnection structure formed by a dual damascene process by using the low-dielectric material for the second insulating film acting as an etching stopper film.

Other objects and further features of the present invention will become apparent from the following detailed description when read in conjunction with the attached drawings.

### BRIEF DESCRIPTION OF THE DRAWINGS

FIGS. 1A-1F are diagrams showing the fabrication process of a conventional semiconductor device having a multilayer interconnection structure;

FIG. 2 is a diagram explaining the principle of the present invention;

FIGS. 3A-3C are diagrams showing the fabrication process of a semiconductor device according to a first embodiment of the present invention;

FIGS. 4A-4F are diagrams showing the fabrication process of a semiconductor device according to a second embodiment of the present invention;

FIGS. 5A-5E are diagrams showing the fabrication process of a semiconductor device according to a third embodiment of the present invention;

FIGS. 6A-6E are diagrams showing the fabrication process of a semiconductor device according to a fourth embodiment of the present invention;

FIGS. 7A-7E are diagrams showing the fabrication process of a semiconductor device according to a fifth embodiment of the present invention;

FIGS. 8A-8E are diagrams showing the fabrication process of a semiconductor device according to a sixth embodiment of the present invention; and

FIGS. 9A-9D are diagrams showing the fabrication process of a semiconductor device having a SAC structure according to a seventh embodiment of the present invention.

### BEST MODE OF IMPLEMENTING THE INVENTION

### Principle

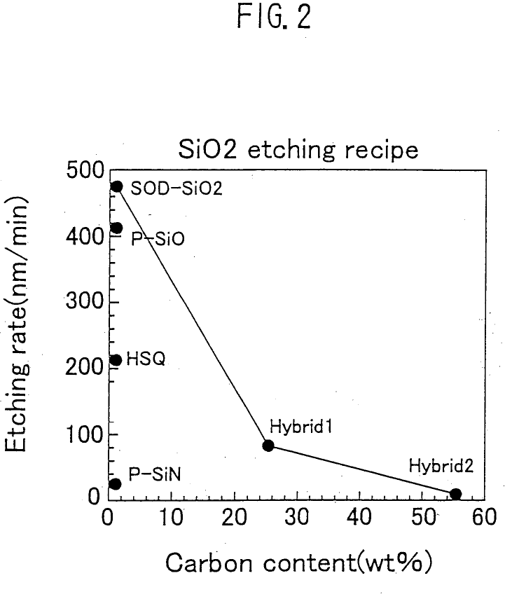

First the principle of the present invention will be explained with reference to FIG. 2, wherein FIG. 2 summarizes the dry etching rate of various SiO₂ films obtained by an experiment conducted by the inventor of the present invention as the foundation of the present invention. In FIG. 2, the vertical axis represents the etching rate while the horizontal axis represents the C concentration incorporated into the SiO₂ insulating film in terms of weight percent (wt %). In the experiment of FIG. 2, the SiO₂ films are subjected to a dry etching process according to a dry etching recipe of an SiO₂ film while using C₄F₈, O₂ and Ar as the etching gas.

Referring to FIG. 2, an experimental point designated as SOD-SiO₂ represents the result for an SOG (spin-on-glass), while the experimental point designated as P—SiO₂ represents the result for an SiO₂ film formed by a plasma CVD process. It should be noted that these SiO₂ films have a large specific dielectric constant of 4.0 or more.

Further, the experimental point designated as HSQ in FIG. 2 represents the result with regard to an SiO₂ film in which hydrogen atoms (H) are incorporated therein in the form of Si—H. The foregoing SiO₂ film designated by HSQ has a characteristically low-dielectric constant of 2.8-2.9. Further, the experimental point designated in FIG. 2 as SIN represents the case in which an SiN film formed by a plasma CVD process is subjected to a dry etching process according to the recipe for an SiO₂ film. It should be noted that the SiN film has a large specific dielectric constant of as large as 8.0.

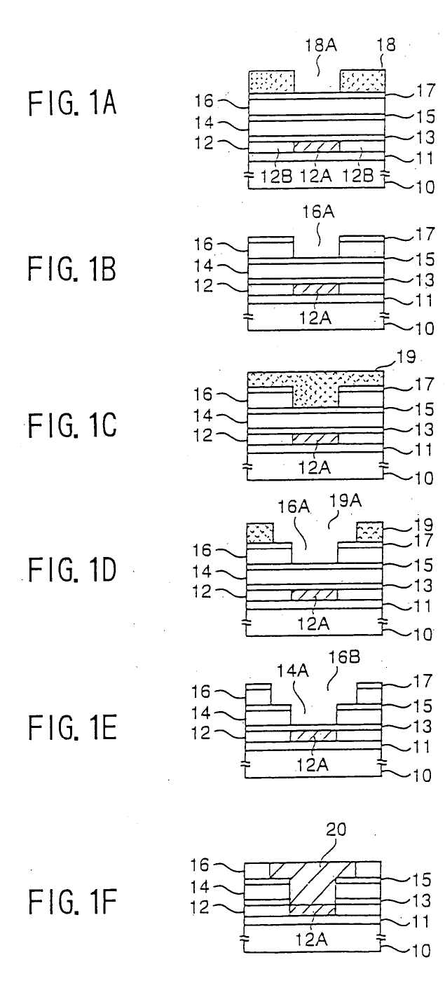

Referring to FIG. 2, it should be noted that the SiO₂ films in the foregoing experimental points are substantially free from C and are characterized by the C concentration of 0 wt %. It can be seen that the SOG film (SOD-SiO₂) and the plasma-CVD SiO₂ film are etched with a rate exceeding 400 nm/min, while the etching rate of the plasma-CVD SiN film (P—SiN) is reduced to 20-30 nm/min. Thus, an etching selectivity in the factor of ten (10) or more is secured between the plasma-CVD SiN film and the SOG film or between the plasma-CVD SiN film and the plasma-CVD SiO₂ film. On the other hand, the use of such an SiN film cancels out the advantageous effect of low-dielectric interlayer insulating film substantially when applied to the multilayer interconnection structure represented in FIG. 1F, due to the large specific dielectric constant thereof.

Meanwhile, the inventor of the present invention has discovered, in the experiment to apply the dry etching recipe for etching an SiO₂ film to a low-dielectric insulating film that contains C (carbon) in SiO₂ in the form of SiOCH, in that the etching rate decreases below 100 nm/min, provided that the C concentration in the film is about 25 wt %. The result for the SiOCH film is represented in FIG. 2 as “Hybrid 1.” Further, it was discovered that the etching rate decreases further to a value of less than 10 nm/minute when the C concentration in the film has increased to 55 wt %, as represented in FIG. 2 by “Hybrid 2.” It should be noted that these values of the etching rate is comparable with or even smaller than the case a plasma-CVD SiN film is subjected to a dry etching process by the recipe for etching an SiO₂ film.

It should be noted that the SiOCH film used in the experiment of FIG. 2 is a commercially available spin-on film, and films of various C concentration levels are available. Further, it is possible to form the SiOCH film by a plasma CVD process.

In such an SiOCH film in which C is contained in the SiO₂ structure in the form of SiOCH component, an Si atom is bonded with a CHₓ group, and thus, the film contains therein the Si—C bonds. The result of FIG. 2 indicates that the etching rate of an SiO₂ film conducted by the etching recipe for etching an SiO₂ film decreases sharply with increasing proportion of the Si—C bonds in the film.

The result of FIG. 2 thus indicates that it is possible use the SiO₂ film containing C with 55 wt % and designated as “Hybrid 2” as the low-dielectric etching stopper film replacing the SiN film.

### FIRST EMBODIMENT

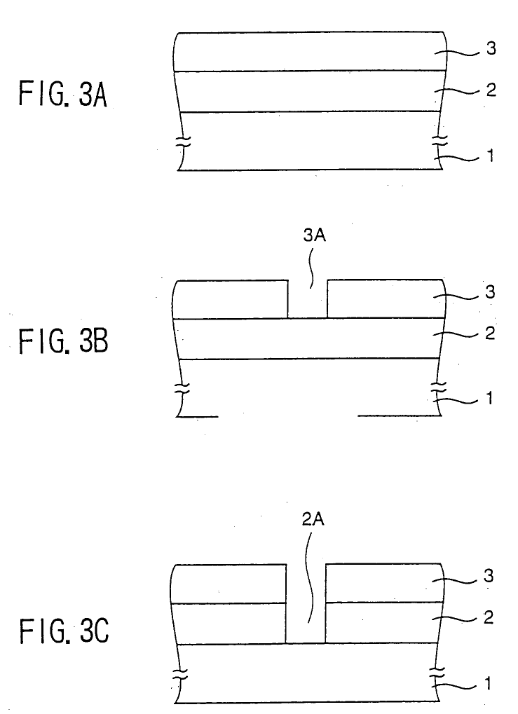

FIGS. 3A-3C show the fabrication process of a semiconductor device according to a first embodiment of the present invention.

Referring to FIG. 3A, a first insulating film 2 is formed on the substrate 1 and a second insulating film 3 is formed on the first insulating film to form a part of the semiconductor device.

Next, in the step of FIG. 3B, an opening 3A is formed in the second insulating film 3, and an opening 2A is formed in the first insulating film 2 in the step of FIG. 3C in alignment with the opening 3A by applying a dry etching process with a recipe for etching the first insulating film while using the second insulating film 3 as a hard mask.

Table 1 below indicates possible combinations of the materials for the foregoing first and second insulating films 2 and 3.

TABLE I

| | | hard mask layer | | |
|---|---|---|---|---|
| | | (insulation layer 3) | | |
| | | | | SiO₂ |
| | | HSQ | organic | with C |
| layer to be | inorganic(SiO₂, | X | ◯ | ◯ |
| etched | SiN, HSQ, etc. | | | |
| (insulation | organic | ◯ | ◯ | ◯ |
| layer 2) | SiO₂ with C | ◯ | ◯ | ◯ |

Referring to TABLE 1, it can be seen that it is possible to carry out the patterning of the insulating film 2 while using the insulating film 3 as a hard mask when an HSQ layer is used for the hard mask layer 3 in any of the cases in which the first insulating film 2 is formed of an organic insulating film and in which the first insulating film 2 is formed of an SiO₂ film containing C, excluding the case in which the first insulating film 2 is formed of SiO₂, SiN or HSQ.

From TABLE 1 above, it should further be noted an aromatic family organic insulating film can be used as an effective hard mask 3 during the process of patterning any of an SiO₂ film, an SiN film, an inorganic insulating film such as an HSQ film, and an SiO₂ film that contains C, with a corresponding etching recipe.

Further, TABLE 1 indicates that the SiO₂ film containing C can function as an effective hard mask in the event the first insulating film 2 is formed of an inorganic insulating film such as SiO₂, SiN or HSQ or in the event the first insulating film 2 is formed of an organic film. The SiO₂ film containing C can also function as an effective hard mask even in the case the second insulating film 3 is formed also of an SiO₂ film containing C, provided that the C concentration is changed between the insulating films 2 and 3 such that a desirable selectivity of etching ratio of larger than 5 is secured.

Referring to the relationship of FIG. 2 again, it can be seen that a desired selectivity of etching is realized-between the first and second insulating films 2 and 3 when a dry etching process is applied to the first insulating film 2 with the etching recipe for etching an SiO₂ film, provided that the C concentration is set to be 25 wt % or less in the first insulating film 2 and the C concentration in the second insulating film 3 is set to be 55 wt % or less.

In the structure of FIG. 3C, it is possible to avoid the problem of increase of stray capacitance even in the case a low-resistance conductor pattern is formed in the opening 2A in view of the use of the low-dielectric materials for the insulating films 2 and 3.

In the case the first insulating film 2 and the second insulating film 3 are formed of SiO₂ containing C, it is possible to deposit the insulating films 2 and 3 in the step of FIG. 3A consecutively and in continuation, by conducting a CVD process consecutively and in continuation in the same reaction vessel. Thereby, the process of forming the multilayer interconnection structure is conducted efficiently.

### SECOND EMBODIMENT

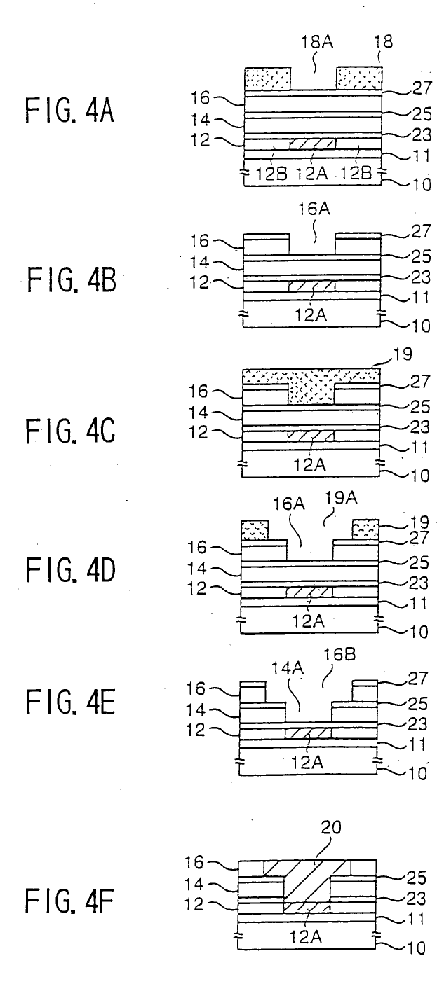

FIGS. 4A-4F are diagrams showing the fabrication process of a semiconductor device having a multilayer interconnection structure according to a second embodiment of the present invention, wherein those parts corresponding to the parts described previously are designated by the same reference numerals and the description thereof will be omitted.

Referring to FIG. 4A, the step corresponds to the step of FIG. 1A described before and a structure similar to the layered structure of FIG. 1A is formed on a substrate 10, except that the structure of FIG. 4A uses etching stopper layers 23, 25 and 27 of SiOCH containing C with a concentration of about 55 wt % in place of the etching stopper films 13, 15 and 17.

Next, in the step of FIG. 4B, the SiOCH film 27 is subjected to a dry etching process while using the resist pattern 18 as a mask, while applying thereto an etching recipe for etching an SiN film, and an opening is formed in the SiOCH film 27 in correspondence to the resist opening 18A. It should be noted that the resist opening 18A corresponds to the contact hole to be formed in the multilayer interconnection structure. After the formation of the opening in the SiOCH film 27, the resist pattern 18 is removed and the interlayer insulating film 16 underneath the SiOCH film 27 is applied with a dry etching process to form an opening 16A therein in correspondence to the resist opening 18A while using the SiOCH film 27 as a hard mask. It is also possible to conduct the step of forming the opening 16A while leaving the resist pattern 18 on the SiOCH film 27.

Next, in the step of FIG. 4C, a resist film 19 is formed on the structure of FIG. 4B, and the resist film 19 thus formed is subjected to a photolithographic process in the step of FIG. 4D to form a resist opening 19A in correspondence to an interconnection groove to be formed in the multilayer interconnection structure. As a result of the formation of the resist opening 19A, a part of the SiOCH film 27 including the opening 16A formed in the interlayer insulating film 16 is exposed. It should be noted that opening 16A exposes the top surface of the SiOCH film 25 at the bottom part thereof.

Next, in the step of FIG. 4E, the exposed part of the SiOCH film 27 exposed at the resist opening 19A is removed by applying thereto a dry etching process with an etching recipe for etching an SiN film while using the resist pattern 19 as a mask. By conducting the dry etching process, the SiOCH film 25 exposed at the bottom part of the opening 16A is also removed simultaneously, and the interlayer insulating film 25 is exposed at the resist opening 19A. Further, the interlayer insulating film 14 is exposed at the opening 16A.

Next, in the step of FIG. 4E, a dry etching process is applied to the structure thus obtained according to the etching recipe of an SiO₂ film, and an opening 16B is formed in the interlayer insulating film 16 in correspondence to the resist opening 19A and hence the pattern of the interconnection groove to be formed. Simultaneously to the formation of the opening 16B, an opening 14A is formed in the interlayer insulating film 14 in correspondence to the contact hole to be formed.

Next, in the step of FIG. 4F, the SiOCH film 27 on the interlayer insulating film 16 is removed together with the SiOCH film 25 exposed at the opening 16B and further with the SiOCH film 23 exposed at the opening 14A, by conducting a dry etching process with an etching recipe for an SiN film.

The interconnection groove thus formed by the opening 16B and the contact hole thus formed by the opening 14A are filled with a conductive layer such as Cu. By removing the Cu layer locating above the interlayer insulating film 16 by a CMP process, a conductor pattern 20 represented in FIG. 4F is obtained in electrical contact with the underlying interconnection pattern 12A at the contact hole 14A.

In the present embodiment, it is preferable to use a low-dielectric inorganic film such as a F-doped SiO₂ film, an HSQ film such as an SiOH film or a porous film for the interlayer insulating films 14 and 16. Alternatively, it is possible to use an organic SOG film or an aromatic family organic film for the low-dielectric interlayer insulating films 14 and 16. Of course, it is possible to use a CVD-SiO₂ film or an SOG film for the interlayer insulating films 14 and 16.

By using a low-dielectric organic or inorganic film for the interlayer insulating films 14 and 16, it becomes possible to decrease the overall dielectric constant of the multilayer interconnection structure, and the operational speed of the semiconductor device is improved.

It should be noted that the SiOCH films 23, 25 and 27 may be formed by a spin-coating process or a plasma CVD process. In the event the SiOCH film 23, 25 and 27 are formed by a plasma CVD process in the step of FIG. 4A, it is possible to form the films 23, 25 and 27 in continuation with the process of forming the other films 14 and 16, without taking out the substrate from the plasma CVD apparatus to the atmospheric environment.

In the event the SiOCH films 23, 25 and 27 are formed by a spin-coating process, it becomes possible to realize a large etching selectivity by combining these films with an SOG film as explained with reference to FIG. 2. This feature will be used in a clustered hard mask process to be described later.

### THIRD EMBODIMENT

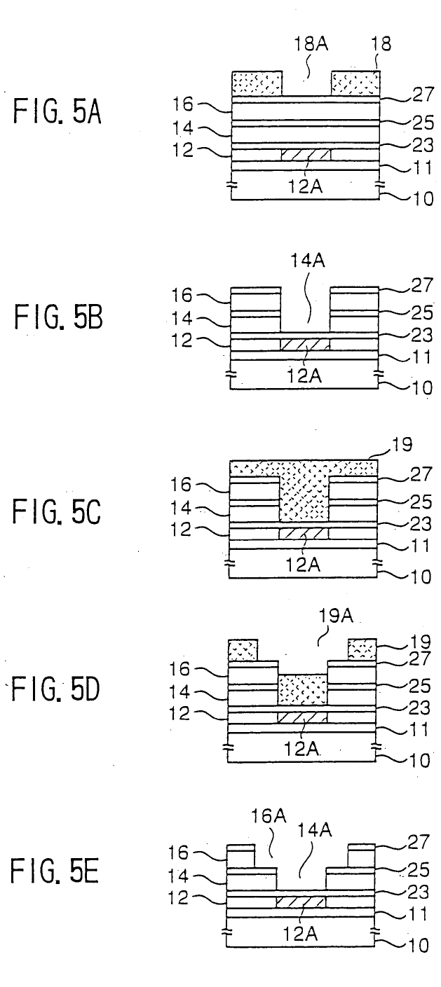

FIGS. 5A-5E are diagrams showing the fabrication process of a semiconductor device according to a third embodiment of the present invention wherein those parts corresponding to the parts described previously are designated by the same reference numerals and the description thereof will be omitted

Referring to FIG. 5A corresponding to the step of FIG. 4A, a layered structure is formed on the interconnection layer 12 provided on the interlayer insulating film 11 on the Si substrate, by consecutively depositing the SiOCH film 23, the interlayer insulating film 14, the SiOCH film 25, the interlayer insulating film 16 and the SiOCH film 27. Further, the resist pattern 18 is formed on a layered structure thus formed, wherein the resist pattern 18 has the resist opening 18A corresponding to a contact hole to be formed in the multilayer interconnection structure, similarly to the embodiments described previously.

Next, in the step of FIG. 5B, the SiOCH film 27 is patterned by an etching recipe for etching an SiN film while using the resist pattern 18 as a mask, to form an opening (not shown) in correspondence to the resist opening 18A.

As the resist opening 18A thus formed exposes the underlying interlayer insulating film 16, the exposed insulating film 16 is applied with an etching process with an etching recipe for etching an SiO₂ film, wherein the etching process is continued until the SiOCH film 25 is exposed. Thereby, an opening is formed in the interlayer insulating film 16 in correspondence with the resist opening 18A.

The SiOCH film 25 thus exposed is then applied with an etching recipe for etching an SiN film, and an opening is formed in the SiOCH film 25 in correspondence to the resist opening 18A so as to expose the underlying interlayer insulating film 14. The interlayer insulating film 14 thus exposed is then applied with an etching process with an etching recipe for etching an SiO₂ film and an opening 14A is formed in the interlayer insulating film 14 in correspondence to the foregoing resist opening 18A. It should be noted that the opening 14A thus formed extends consecutively through the SiOCH film 27, the interlayer insulating film 16, the SiOCH film 25 and the interlayer insulating film 14, and exposes the SiOCH film 23 at the bottom part thereof.

Next, in the step of FIG. 5C, the resist pattern 18 is removed and the resist film 19 is newly provided on the structure of FIG. 5B so as to fill the opening 14A. The resist film 19 thus formed is then patterned in the step of FIG. 5D by a photolithographic patterning process, and the resist opening 19A is formed in the resist film 19 in correspondence to the interconnection groove to be formed in the multilayer interconnection structure.

Next, in the step of FIG. 5E, the resist film 19 thus formed with the resist opening 19A is used as a mask, and the SiOCH film 27 is subjected to a dry etching process with an etching recipe for etching an SiN film. Thereby, an opening is formed in the SiOCH film 27 in correspondence to the resist opening 19A so as to expose the underlying interlayer insulating film 16. Further, the resist pattern 19 is removed and the interlayer insulating film 16 exposed by the opening formed in the SiOCH film 27 is removed by a dry etching process with a recipe for etching an SiO₂ film while using the SiOCH film 27 as a mask. As a result, an opening 16A corresponding to the interconnection groove to be formed in the multilayer interconnection structure is formed in the interlayer insulating film 16 in correspondence to the resist opening 19A.

The dry etching process for forming the opening 16A stops spontaneously upon exposure of the SiOCH film 25, and the exposed SiOCH films 27, 25 and 23 are removed thereafter. By filling the openings 16A and 14A by a conductive layer such as a Cu layer, the multilayer interconnection structure explained previously with reference to FIG. 4F is obtained.

In the present embodiment, too, it is possible to use a F-doped SiO₂ film, an HSQ film such as an SiOH film or a low-dielectric organic insulating film of aromatic family for the interlayer insulating films 14 and 16, and the overall dielectric constant of the multilayer interconnection structure is reduced. As a result, the semiconductor device having such a multilayer interconnection structure shows an improved operational speed.

### FOURTH EMBODIMENT

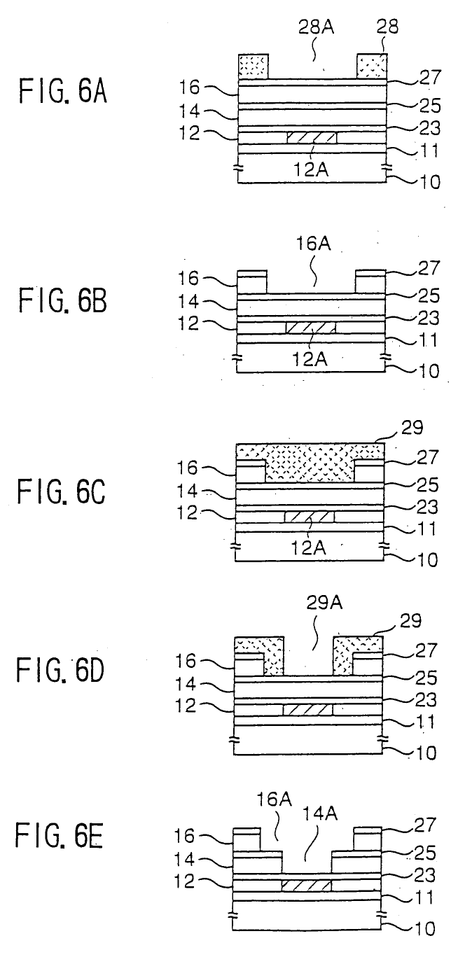

FIGS. 6A-6E show the fabrication process of a semiconductor device according to a fourth embodiment of the present invention, wherein those parts corresponding to the-parts described previously are designated by the same reference numerals and the description thereof will be omitted.

Referring to FIG. 6A, the step of FIG. 6A is substantially identical with the process of FIG. 4A or FIG. 5A and a layered structure is formed on the interconnection layer 12 provided on the interlayer insulating film 11 on the Si substrate 10 by consecutively depositing the SiOCH film 23, the interlayer insulating film 14, the SiOCH film 25, the interlayer insulating film 16 and the SiOCH film 27 on the interconnection layer 12. Further, a resist pattern 28 is provided on the layered structure with a resist opening 28A formed in correspondence to the interconnection groove to be formed in the multilayer interconnection structure.

Next, in the step of FIG. 6B, the SiOCH film 27 is subjected to an etching process conducted according to an etching recipe for etching an SiN film while using the resist pattern 28 as a mask. As a result, an opening (not shown) is formed in the SiOCH film 27 in correspondence to the foregoing resist opening 28A such that the opening exposes the interlayer insulating film 16 located underneath the SiOCH film 27. Thus, the interlayer insulating film 16 thus exposed is subjected to an etching process according to an etching recipe for etching an SiO₂ film, and the opening 16A is formed in the interlayer insulating film 16 in correspondence to the resist opening 28A, and hence in correspondence to the interconnection groove to be formed, so as to expose the SiOCH film 25.

Next, in the step of FIG. 6C, the resist film 28 is removed and a new resist film 29 is formed on the structure of FIG. 6B such that the resist film 29 fills the opening 16A. Further, the resist film 29 is patterned in the step of FIG. 6D by a photolithographic process and a resist opening 29A is formed in the resist film 29 in correspondence to the contact hole to be formed.

Next, in the step of FIG. 6E, the resist film 29 having the resist opening 29A thus formed is used as a mask, and the SiOCH film 25 is subjected to a dry etching process with a recipe for etching an SiN film so as to remove the exposed part of the SiOCH film 25. Thereby, an opening is formed in the SiOCH film 25 in correspondence to the resist opening 29A so as to expose the underlying interlayer insulating film 14.

After the resist film 29 is removed, the SiOCH film 27 and the SiOCH film 25 are used as a hard mask and the interlayer insulating film 14 is etched by a dry etching process with a recipe for etching an SiO₂ film. As a result, the opening 14A is formed in the interlayer insulating film 14 in correspondence to the resist opening 29A and hence the contact hole to be formed in the multilayer interconnection structure.

The dry etching process for forming the opening 14A stops spontaneously upon the exposure of the SiOCH film 29. After the exposure of the SiOCH film 23, the exposed part of the SiOCH film 23 is removed simultaneously with the exposed part of the SiOCH films 27 and 25, and the opening 16A and the opening 14A are filled with a conductive layer such as a Cu layer. Thereby, the multilayer interconnection structure explained with reference to FIG. 4F is obtained.

In the present embodiment, too, it is possible to use any of a low-dielectric inorganic insulating film such as F-doped SiO₂ film, an HSQ film such as an SiOH film or a porous film, or an organic SOG film, or a low-dielectric organic insulating film of the aromatic family. The multilayer interconnection structure of the present embodiment has an advantageous feature of reduced overall dielectric constant, and the semiconductor device having the multilayer interconnection structure shows an improved operational speed.

### FIFTH EMBODIMENT

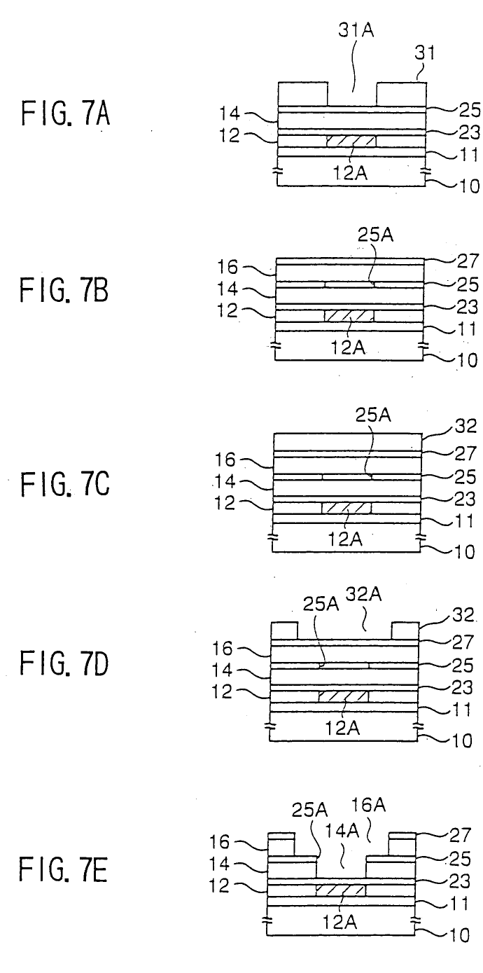

FIGS. 7A-7E are diagrams showing the fabrication process of a semiconductor device according to a fifth embodiment of the present invention, wherein those parts corresponding to the parts described previously are designated by the same reference numerals and the description thereof will be omitted.

Referring to FIG. 7A, a layered structure is formed on the interconnection layer 12 provided on the interlayer insulating film 11 on the Si substrate 10 by consecutively depositing the SiOCH film 23, the interlayer insulating film 14 and the SiOCH film 25. Further, a resist pattern 31 is formed on the foregoing SiOCH film 25, wherein the resist pattern 31 is formed with a resist opening 31A corresponding to a contact hole to be formed in the multilayer interconnection structure.

It should be noted that the resist opening 31A exposes the SiOCH film 25, and the SiOCH film 25 is subjected to a dry etching process in the step of FIG. 7B with an etching recipe for etching an SiN film. As a result, an opening 25A is formed in the SiOCH film 25 in correspondence to the resist opening 31A.

Next, in the step of FIG. 7B, the interlayer insulating film 16 is deposited on the SiOCH film 25 so as to fill the opening 25A, and the SiOCH film 27 is deposited further on the interlayer insulating film 16.

Next, in the step of FIG. 7C, a resist film 32 is applied on the SiOCH film 27 and the resist film 32 is patterned in the step of FIG. 7D by a photolithographic patterning process. As a result, an opening 32A is formed in the multilayer interconnection structure in correspondence to the interconnection groove to be formed.

Next, in the step of FIG. 7E, the resist film 32 is used as a mask and the SiOCH film 27 exposed at the opening 32A is subjected to a dry etching process while using the dry etching recipe for etching an SiN film. The dry etching is continued until the underlying interlayer insulating film 16 is exposed.

Next, the interlayer insulating film 16 is etched with the etching recipe for etching an SiO₂ film, and the opening 16A is formed in the interlayer insulating film 16 in correspondence to the resist opening 32A, and hence in correspondence to the interconnection groove to be formed. It should be noted that the dry etching process of the interlayer insulating film 16A stops in the part where the SiOCH film 25 is formed upon the exposure of the SiOCH film 25, while the dry etching process proceeds further into the interlayer insulating film 14 in the part where the opening 25A is formed in the film 25. As a result, the opening 14A is formed in the interlayer insulating film 14 in correspondence to the opening 25A, and hence the contact hole to be formed in the multilayer interconnection structure.

It should be noted that the dry etching process for forming the opening 14A stops upon the exposure of the SiOCH film 23. Thus, the SiOCH films 27, 25 and 23 are removed, and the openings 16A and 14A are filled with a conductive layer such as a Cu layer. Thereby, the multilayer interconnection structure of FIG. 4F is obtained.

In the present embodiment, too, it is possible to use a low-dielectric inorganic insulating film such as a F-doped SiO2 film, an HSQ film such as an SiOH film or a porous film or an organic SOG film or a low-dielectric organic insulating film of the aromatic family. The multilayer interconnection structure of the present embodiment has a reduced dielectric constant and the semiconductor device having such a multilayer interconnection structure shows an improved operational speed.

### SIXTH EMBODIMENT

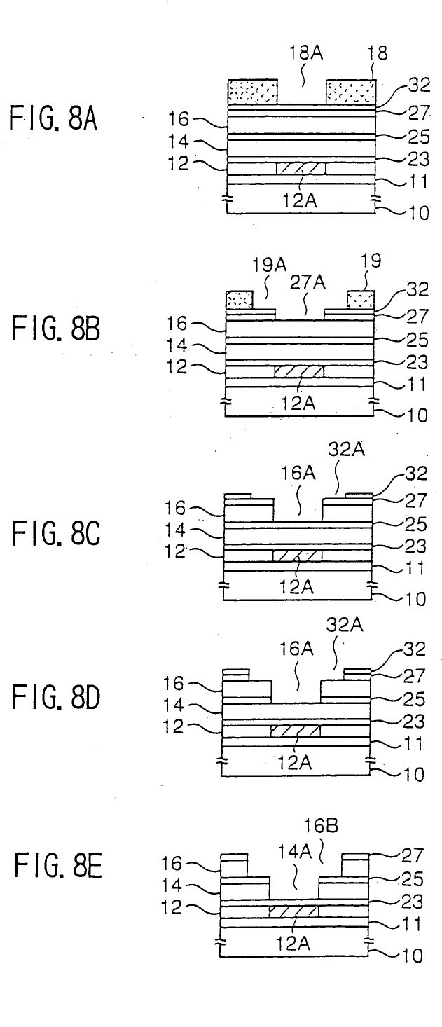

FIGS. 8A-8E show the fabrication process of a semiconductor device having a multilayer interconnection structure according to an eighth embodiment of the present invention, wherein the multilayer interconnection structure of the present embodiment uses a so-called clustered hard mask. In the drawings, those parts corresponding to the parts described previously are designated by the same reference numerals and the description thereof will be omitted.

In the present embodiment, the process starts with the step of FIG. 8A in which a layered structure is formed on the interconnection layer 12 including therein the interconnection pattern 12A, by consecutively depositing the SiOCH film 23, the interlayer insulating film 14, the SiOCH film 25, the interlayer insulating film 16 and the SiOCH film 27 similarly to other embodiments, and an SiO₂ film 32 is deposited further on the SiOCH film 27 by a plasma CVD process or by a spin-coating process. Further, the resist pattern 18 is formed on the SiO₂ film 32 such that the resist pattern 18 includes the resist opening 18A in correspondence to the contact hole to be formed in the multilayer interconnection structure. It should be noted that the SiOCH film 27 and the SiO₂ film 32 function as a hard mask film and form together a so-called clustered hard mask structure.

In the step of FIG. 8A, a dry etching process is applied further to the SiO₂ film 32 with an etching recipe for etching an SiO₂ film while using the resist film 18 as a mask, and an opening is formed in the SiO₂ film 32 in correspondence to the resist opening 18A. The opening thus formed in the SiO₂ film exposes the underlying SiOCH film 27.

Next, the etching recipe is changed to the one for etching an SiN film, and the exposed part of the SiOCH film 27 is subjected to a dry etching process in the step of FIG. 8A with the new etching recipe. As a result, the opening 27A is formed in the SiOCH film 27 in correspondence to the resist opening 18A, wherein the opening 27A exposes the interlayer insulating film 16 as represented in FIG. 8B.

After the formation of the opening 27A in the step of. FIG. 8B, the resist pattern 18 is removed and the resist pattern 19 is provided on the SiO₂ film 32 such that the resist opening 19A exposes the SiO₂ film 32 in conformity with a pattern of the interconnection groove to be formed in the multilayer interconnection structure. In the step of FIG. 8C, the exposed part of the SiO₂ film 32 is removed by applying a dry etching process conducted with the dry etching recipe for etching an SiO₂ film.

In the foregoing dry etching process of FIG. 8C, the SiOCH film 27 functions as an etching stopper, and the opening 32A formed in the SiO₂ film 32 in correspondence to the resist opening 19A exposes the SiOCH film 27 as represented in FIG. 8C.

In the step of FIG. 8C, it should be noted that the dry etching process proceeds further into the interlayer insulating film 16 at the opening 27A simultaneously to the dry etching process of the SiO₂ film 32, and the opening 16A is formed in the interlayer insulating film 16 in correspondence to the opening 27A. In this process, it should be noted that the SiOCH film 27 is used as the hard mask. As a result of the dry etching process, the SiOCH film 25 is exposed at the opening 16A.

Next, in the step of FIG. 8D, the etching recipe is changed to the one for etching an SiN film, and the SiOCH film 27 exposed at the opening 32A and the SiOCH film 25 exposed a the opening 16A are removed simultaneously. As a result, the interlayer insulating film 16 is exposed at the opening 32A and the interlayer insulating film 14 is exposed at the opening 16A.

Next, in the step of FIG. 8E, the etching recipe is changed to the one for etching an SiO₂ film, and the interlayer insulating film 16 exposed at the opening 32A and the interlayer insulating film 14 exposed at the opening 16A are removed by conducting a dry etching process with the new etching recipe for an SiO₂ film. As a result, the interlayer insulating film 16 is formed with the opening 16B in correspondence to the opening 19A and hence the interconnection groove to be formed. Simultaneously, the interlayer insulating film 14 is formed with the opening 14A corresponding to the resist opening 18A and hence the contact hole to be formed.

Further, the SiOCH film 27 is removed in the structure of FIG. 8E together with the exposed part of the SiOCH film 25 and the SiOCH film 23, and the opening 16A and the opening 14A thus obtained are filled with a conductor layer such as a Cu layer. Thereby, the multilayer interconnection structure explained with reference to FIG. 4F is obtained.

It should be noted that the present embodiment utilizes the difference of etching rate between the SiO₂ film 32 used as a first hard mask film and the SiOCH film 27 used as a second hard mask film in the step of FIG. 8C. Thereby, it is possible to realize a very large selectivity of etching rate between the hard mask film 32 and the hard mask film 27 by using a spin-coated SOG film for the hard mask film 32 and by using a spin-coated SiOCH film for the hard mask film 27 in view of FIG. 2 explained before and as can be seen from TABLE 2 below.

TABLE II

| | | etching | etching |
|---|---|---|---|
| | | selectivity of | selectivity of |
| | | HM1 to HM2 | HM2 to HM1 |
| CASE 1 | HM1 = CVD-SiO₂ | 17 | 4.8 |
| | HM2 = CVD-SiN | | |
| | HM1 = SOD-SiO₂ | | |
| CASE 2 | RM2 = SOD-Hybrid | 100 | 13 |

Referring to TABLE II, CASE 1 represents a typical conventional case of using a CVD-SiO₂ film for the first hard mask layer (HM1) 32 in combination with a CVD-SiN film for the second hard mask layer (HM2) 27, while CASE 2 represents the present embodiment that uses an SOG film (SOD-SiO₂) for the first hard mask layer (HM1) 32 in combination with the SiOCH film (SOD-Hybrid) for the second hard mask layer (HM2) 27.

As can be seen from TABLE II, an etching selectivity ratio of only 17 was reached in the conventional case of using a CVD-SiN film for the second hard mask layer 27 in combination with a CVD-SiO₂ film for the first hard mask layer 32. On the other hand, an etching selectivity of as large as 100 is achieved when an SOG is used for the first hard mask layer 32 and the SiOCH film having the composition of Hybrid 2 of FIG. 2 is used for the second hard mask layer 27.

Further, TABLE II indicates that an etching selectivity of about 13 is achieved when conducting a dry etching of the SiOCH film while using the SOG film as an etching stopper, wherein this value of the etching selectivity is larger than the etching selectivity of about 4.8, which is achieved in the conventional case of dry etching a CVD-SiN film while using a CVD-SiO₂ film as an etching stopper. It should be noted that the etching rate of the SiOCH film for the case of applying a dry etching process with an etching recipe for an SiN film is slightly larger than the etching rate for the case of dry-etching the plasma-CVD film with the same etching recipe, provided that the SiOCH film has the composition of Hybrid 2.

It should be noted that the SiOCH film 27 thus formed by a spin-coating process can cover the underlying interlayer insulating film 16 without forming a defect at the interface between the film 17 and the interlayer insulating film 16.

In the present embodiment, too, it becomes possible to use various low-dielectric inorganic films, such as a F-doped SiO₂ film, an HSQ film including an SiOH film or a porous insulating film or an organic SOG film or a low-dielectric organic film of the aromatic family, for the interlayer insulating films 14 and 16. Thereby the overall dielectric constant of the multilayer interconnection structure is reduced and the operational speed of the semiconductor device is improved.

It should be noted that the upper hard mask layer 32 of the clustered hard mask structure of the present embodiment is by no means limited to an SiO₂ film but an SiOCH film having a lower C concentration level may also be used.

### SEVENTH EMBODIMENT

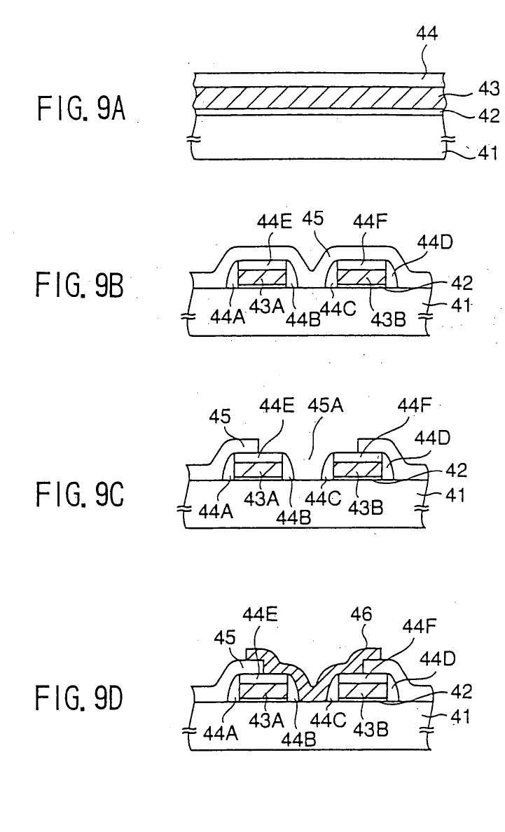

Next, the fabrication process of a semiconductor device having a SAC (self-aligned contact) structure according to a seventh embodiment of the present invention will be described with reference to FIGS. 9A-9D.

Referring to FIG. 9A, a gate oxide film 42 is formed on a Si substrate 41 doped to the p-type or n-type by a thermal oxidation process, and a polysilicon film 43 is formed on the gate oxide film 42 by a CVD process. Further, an SiOCH film 44 explained before is formed on the polysilicon film 43 by a spin-coating process.

Next, in the step of FIG. 9B, the SiOCH film 44 and the underlying polysilicon film 43 are patterned by a photolithographic patterning process, and polysilicon electrodes 43A and 43B are formed on the substrate 41 adjacent with each other. As a result of the patterning of the SiOCH film 44, SiOCH patterns 44E and 44F are formed on the polysilicon gate electrodes 43A and 43B as a result of the foregoing patterning process of the SiOCH film 44.

In the step of FIG. 9B, an ion implantation process is conducted into the Si substrate 41 while using the gate electrodes 43A and 43B as a self-aligned mask, and diffusion regions not illustrated are formed in the substrate 41 adjacent to the gate electrodes 43A and 43B. Further, another SiOCH film is provided so as to cover the gate electrodes 43A and 43B including the SiOCH patterns 44E and 44F by a CVD process, and the SiOCH film thus deposited is subjected to an etch-back process while using the etching recipe for etching an SiN film. As a result, the gate electrode 43A is formed with sidewall insulating films 44A and 44B of SiOCH on the both sidewalls thereof. Similarly, the gate electrode 43B is formed with sidewall insulating films 44C and 44D of SiOCH on the both sidewalls thereof.

Next, an SiO₂ film 45 is deposited on the Si substrate 41 so as to cover the foregoing gate electrodes 43A and 43B including intervening SiOCH films 44A-44F by a plasma CVD process.

Next, in the step of FIG. 9C, a contact hole 45A is formed in the SiO₂ film 45 so as to expose the diffusion region formed between the gate electrode 43A and the gate electrode 43B, by applying a dry etching process to the SiO₂ film 45 with the etching recipe for etching an SiO₂ film. Thereby, such a dry etching process exposes the SiOCH sidewall insulating films 44A-44F on the gate electrodes 43A and 43B, wherein the dry etching process stops spontaneously upon the exposure of the sidewall insulating films 44A-44F due to the selectivity of the etching process as explained with reference to FIG. 2.

Further, an electrode 46 is provided in the step of FIG. 9D on the SiO₂ film 44 so as to cover the contact hole 45A.

According to the present embodiment, it is possible to increase the selectivity of dry etching process between any of the SiOCH etching stopper films 44A-44F and the SiO₂ film 45 in the step of FIG. 9C as compared with the conventional case of using SiN for the etching stopper, and the problem of decrease of the thickness of the etching stopper films 44A-44F and associated problem of gate leakage current are successfully eliminated. Because of the very small dielectric constant of the etching stopper films 44A-44F, the semiconductor device of the present embodiment shows an improved operational speed.

Further, the present invention is not limited to the embodiments described heretofore, but various variations and modifications may be made without departing from the scope of the invention.

### Industrial Applicability

According to the present invention, it is possible to decrease the overall dielectric constant of a multilayer interconnection structure by using a low-dielectric insulating film for the etching stopper film or a hard mask film, and the operational speed of the semiconductor device is improved. Further, such a low-dielectric etching stopper film can be used for a semiconductor device having a SAC structure.

1. A method of fabricating a semiconductor device, comprising the steps of:
depositing a second insulating film on a first insulating film;
patterning said second insulating film to form an opening therein; and
etching said first insulating film while using said second insulating film as an etching mask,
wherein a low-dielectric film is used for said second insulating film.

2. A method as claimed in claim 1, wherein said first insulating film comprises an inorganic insulating film and said second insulating film comprises an organic insulating film.

3. A method as claimed in claim 2, wherein said first insulating film is selected from the group consisting of an SiO₂ film, an SiN film and a hydrogen silsesquioxane film.

4. A method as claimed in claim 1, wherein said first insulating film comprises an inorganic film and said second insulating film comprises an SiO₂ film containing C.

5. A method as claimed in claim 4, wherein said second insulating film contains C with a concentration such that said second insulating film shows an etching selectivity with respect to an etching recipe for etching said first insulating film.

6. A method as claimed in claim 5, wherein said concentration of C is chosen such that said second insulating film shows an etching rate smaller than an etching rate of said first insulating film by a factor of ⅕ or less when said etching recipe for etching said first insulating film is applied.

7. A method as claimed in claim 4, wherein said second insulating film contains therein C with a concentration exceeding about 25 wt %.

8. A method as claimed in claim 4, wherein said second insulating film contains therein C with a concentration of about 55 wt %.

9. A method as claimed in claim 1, wherein said first insulation film comprises an organic insulating film and said second insulating film comprises a hydrogen silsesquioxane film.

10. A method as claimed in claim 1, wherein said first insulating film comprises an organic insulating film and said second insulating film comprises an organic insulating film.

11. A method as claimed in claim 1, wherein said first insulating film comprises an organic insulating film and said second insulating film comprises an SiO₂ film containing C.

12. A method as claimed in claim 11, wherein said second insulating film contains C with a concentration such that said second insulating film shows an etching selectivity with regard to an etching recipe for etching said first insulating film.

13. A method as claimed in claim 12, wherein said C concentration is chosen such that said second insulating film shows an etching rate smaller than an etching rate of said first insulating film by a factor of ⅕ or less when said etching recipe for said first insulating film is applied.

14. A method as claimed in claim 11, wherein said second insulating film contains therein C with a concentration exceeding about 25 wt %.

15. A method as claimed in claim 11, wherein said second insulating film contains therein C with a concentration of about 55 wt %.

16. A method as claimed in claim 11, wherein said second insulating film comprises a hydrogen silsesquioxane film.

17. A method as claimed in claim 1, wherein said first insulating film comprises an SiO₂ film containing C, and wherein said second insulating film comprises an organic insulating film.

18. A method as claimed in claim 17, wherein said first insulating film contains C with a concentration such that said first insulating film shows an etching selectivity with regard to an etching recipe for etching said second insulating film.

19. A method as claimed in claim 18, wherein said concentration of C is chosen such that said first insulating film shows an etching rate smaller than an etching rate of said second insulating film by a factor of ⅕ or less when said etching recipe for etching said second insulating film is applied.

20. A method as claimed in claim 17, wherein said first insulating film contains therein C with a concentration exceeding about 25 wt %.

21. A method as claimed in claim 17, wherein said first insulating film contains therein C with a concentration of about 55 wt %.

22. A method as claimed in claim 1, wherein said first insulating film comprises an SiO₂ film containing therein C, and said second insulating film comprises an SiO₂ film containing therein C.

23. A method as claimed in claim 22, wherein said first and second insulating films containing C with respective concentrations chosen such that-said second insulating film shows an etching selectivity with regard to an etching recipe for etching said first insulating film.

24. A method as claimed in claim 23, wherein said C concentrations of said first and second insulating films are chosen such that said second insulating film shows an etching rate smaller than an etching rate of said first insulating film by a factor of ⅕ or less when said etching recipe for etching said first insulating film is applied.

25. A method as claimed in claim 1, wherein said first and second insulating films are formed consecutively in a common deposition apparatus.

26. A semiconductor device, comprising:
a substrate; and
a multilayer interconnection structure provided on said substrate,
said multilayer interconnection structure comprising:
an interlayer insulating film having a first opening;
an etching stopper film provided on said interlayer insulating film with a second opening aligned with said first opening; and
a conductor pattern filling said first and second openings,
wherein said etching stopper film is formed of a low-dielectric film.

27. A semiconductor device as claimed in claim 26, wherein said interlayer insulating film comprises an inorganic insulating film and wherein said etching stopper film comprises an organic insulating film.

28. A semiconductor device as claimed in claim 26, wherein said inorganic interlayer insulating film is selected from the group consisting of an SiO₂ film, an SiN film and a hydrogen silsesquioxane film.

29. A semiconductor device as claimed in claim 26, wherein said first interlayer insulating film comprises an inorganic insulating film and wherein said etching stopper film comprises an SiO₂ film containing therein C.

30. A semiconductor device as claimed in claim 29, wherein said etching stopper film contains C with a concentration exceeding about 25 wt %.

31. A semiconductor device as claimed in claim 29, wherein said etching film contains C with a concentration of about 55 wt %.

32. A semiconductor device as claimed in claim 29, wherein said interlayer insulating film is selected from the group consisting of an SiO₂ film and a hydrogen silsesquioxane film.

33. A semiconductor device as claimed in claim 26, wherein said interlayer insulating film comprises an organic insulating film and said etching stopper film comprises hydrogen silsesquioxane film.

34. A semiconductor device as claimed in claim 26, wherein said interlayer insulation film comprises an organic insulating film and said etching stopper film comprises an SiO₂ film containing therein C.

35. A semiconductor device as claimed in claim 34, wherein said etching stopper film contains C with a concentration exceeding about 25 wt %.

36. A semiconductor device as claimed in claim 34, wherein said etching stopper film contains C with a concentration of about 55 wt %.

37. A semiconductor device as claimed in claim 26, wherein said interlayer insulating film and said etching stopper film are formed of an SiO₂ film containing C with respective concentrations such that said etching stopper film shows an etching rate smaller than an etching rate of said interlayer insulating film by a factor of ⅕ or less with regard to an etching recipe for etching said interlayer insulating film.

38. A semiconductor device as claimed in claim 37, wherein said etching stopper film contains C with a concentration of about 55 wt % and said interlayer insulating film contains C with a concentration of about 25 wt % or less.

39. A semiconductor device, comprising:
a substrate;
a pair of patterns formed on said substrate; and
a contact hole formed between said pair of patterns,
each of said patterns having a sidewall insulating films thereon, and
wherein said contact hole is defined by said side wall insulating films of said patterns,
said sidewall insulating films comprising a material having a low-dielectric constant.

40. A semiconductor device as claimed in claim 39, wherein said sidewall insulating film comprises an SiO₂ film containing therein C.

41. A semiconductor device as claimed in claim 40, wherein said sidewall insulating film contains C with a concentration exceeding about 25 wt %.

42. A semiconductor device as claimed in claim 40, wherein said sidewall insulating film contains C with a concentration of about 55 wt %.
